(19) United States
(12) Patent Application Publication
(10) Pub. No.: US 2004/0083970 A1
(43) Pub. Date: May 6, 2004

(54) Vacuum processing device

(76) Inventors: Kosuke Imafuku, Yamanashi (JP); Tsuyoshi Hida, Yamanashi (JP)

Correspondence Address: Finnegan Henderson Farabow, Garrett & Dunner, 1300 I Street NW, Washington, DC, 20005, US

(21) Appl. No.: 10/398,031

(22) PCT Filed: Oct. 1, 2001
(86) PCT No.: PCT/JP01/08624

(30) Foreign Application Priority Data
Oct. 2, 2000 (JP) 2000-302124

(51) Int. Cl. C23C 16/00

(52) U.S. Cl. 118/719

(57) ABSTRACT

Maintenance work on an apparatus is facilitated, the maintenance cycle is extended and an improvement in throughput is achieved. A processing chamber 2 and an auxiliary vacuum chamber 3 are connected via a transfer port 20 formed through their wall surfaces. At the inner wall of the transfer port 20, a detachable gate liner 100 constituted of a plurality of members is installed. The maintenance work at the inner wall of the transfer port is facilitated since the gate liner 100 alone simply needs to be disengaged to be washed, replaced or the like. Insulating films 200 and 300 constituted of a rare earth oxide spray-deposit film with high plasma erosion resistance are used to coat the surface of the gate liner 100 and the surface of a gate valve 4 over the area covering the transfer port 20. As a result, damage attributable to plasma does not occur readily at these surfaces, and the extent of metal contamination and dust generation is lowered.

### TECHNICAL FIELD

The present invention relates to a vacuum processing apparatus that implements processing such as etching or chemical vapor deposition on a workpiece which may be, for instance, a semiconductor wafer or a liquid crystal display substrate.

### BACKGROUND ART

Various processing apparatuses are employed to perform different types of processing including etching, chemical vapor deposition, ashing and sputtering while semiconductor devices or the like are processed. In such a processing apparatus, an auxiliary vacuum chamber referred to as load lock chamber is connected to an airtight processing chamber to ensure that no impurity in the atmosphere is allowed to enter the processing chamber. The processing chamber and the auxiliary vacuum chamber are connected with each other through a transfer port formed through wall surfaces of the chambers, and the workpiece is transferred via the transfer port. In addition, a valve element, which can be opened/closed freely, referred to as a gate valve, is provided at each of the transfer ports of the auxiliary vacuum chamber, i.e., the transfer port provided on the atmosphere side and the transfer port provided on the processing chamber side so as to open/close the transfer port.

The transfer port and the gate valve in the processing chamber are located in an area where plasma tends to concentrate readily during an etching process. The transfer port, which is formed as an integrated part of the processing chamber, is normally constituted of aluminum with its surfaces coated with anodic oxidation coating. The gate valve is often constituted by using a similar material. When the anodic oxidation coating coated surfaces are directly exposed to plasma, the coated surfaces become etched and, as a result, the aluminum underneath becomes exposed. In addition, while a processing gas constituted of a halogen compound is often used when manufacturing semiconductors, liquid crystal devices or the like, the halogen ions from such a halogen compound are highly corrosive. When an exposed surface is exposed to such halogen ions, the surface becomes eroded. Also, the deposit of the reaction product subsequently flakes off, thereby generating particles.

Thus, it is necessary to perform maintenance such as cleaning and replacement of the transfer port and the gate valve, which become corroded or contaminated by the particles, as described above. As the extents of corrosion and contamination become higher, the maintenance work must be performed more frequently. Since the apparatus adopts a complex structure, the maintenance process tends to be complicated and time-consuming. If the apparatus frequently has a lengthy down time, the operating rate of the apparatus becomes poor, which leads to low throughput.

An object of the present invention, which has been completed by addressing the problem discussed above, is to provide a vacuum processing apparatus that facilitates maintenance on the apparatus, extends the maintenance cycle and achieves an improvement in the throughput.

### DISCLOSURE OF THE INVENTION

In order to achieve the object described above, the vacuum processing apparatus achieved in a first aspect of the present invention is characterized in that a detachable liner member is provided at the inner wall of a transfer port formed at a wall surface of a vacuum processing chamber, through which a workpiece is transferred.

In addition, the vacuum processing apparatus achieved in a second aspect of the present invention, having a gate valve which opens/closes the workpiece transfer port formed at the wall surface of the vacuum processing chamber, is characterized in that a rare earth oxide spray-deposit film is formed over, at least, the surface of the gate valve covering the transfer port.

To describe the present invention in further detail, the liner member may be constituted of a plurality of members. In addition, the surface of the liner member may be coated with an insulating film. The insulating film may be a rare earth oxide spray-deposit film such as Y₂O₃. The thickness of the insulating film or the rare earth oxide spray-deposit film may be within a range of 50 μm-100 μm.

In the first aspect of the present invention, maintenance work on the inner wall of the transfer port can be achieved by simply cleaning or replacing the disengaged liner member and, thus, it can be completed quickly. As a result, the throughput of the apparatus can be improved.

In the structure achieved in the second aspect of the present invention, the surface of the gate valve, which is vulnerable to damage caused by plasma, is coated with a rare earth oxide spray-deposit film with a high degree of plasma erosion resistance. Since a rare earth oxide has a high melting point and forms a strong chemical bond with oxygen, a stable condition can be maintained even when it is exposed to plasma. As a result, damage does not readily occur and the extents of metal contamination and dust damage can be reduced. In addition, since the maintenance work does not need to be performed on the gate valve often, the throughput of the apparatus is improved.

Since only the damaged liner member needs to be replaced and the entire liner member does not have to be replaced when the liner member is partially damaged, a cost reduction is achieved by adopting structural features which characterize the present invention. In addition, by coating the surface with an insulating film, the surface is protected from the plasma and thus is not etched. Furthermore, by using a rare earth oxide with a high melting point that forms a strong chemical bond with oxygen, a stable state can be maintained even when the surface is exposed to plasma. In other words, the presence of a rare earth oxide spray-deposit film raises the plasma erosion resistance, prevents damage effectively and reduces the extents of the metal contamination and generation of dust. As a result, the frequency of maintenance work on the apparatus can be reduced to achieve an improvement in throughput.

### BRIEF DESCRIPTION OF THE DRAWING

FIG. 1 is a schematic sectional view of an etching apparatus that may adopt the present invention;

FIG. 2 is an enlarged sectional view of an area around the transfer port;

FIG. 3 is a perspective of the gate liner achieved in an embodiment of the present invention; and

FIG. 4A is of sectional view of an assembled gate liner achieved in another embodiment of the present invention; and FIG. 4B is an exploded view of the gate liner.

### BEST MODE FOR CARRYING OUT THE INVENTION

The following is an explanation of preferred embodiments of the vacuum processing apparatus according to the present invention, given in reference to the attached drawings. It is to be noted that the same reference numerals are assigned to members having substantially identical functions and structural features in the following explanation and the attached drawings to preclude the necessity for a repeated explanation thereof.

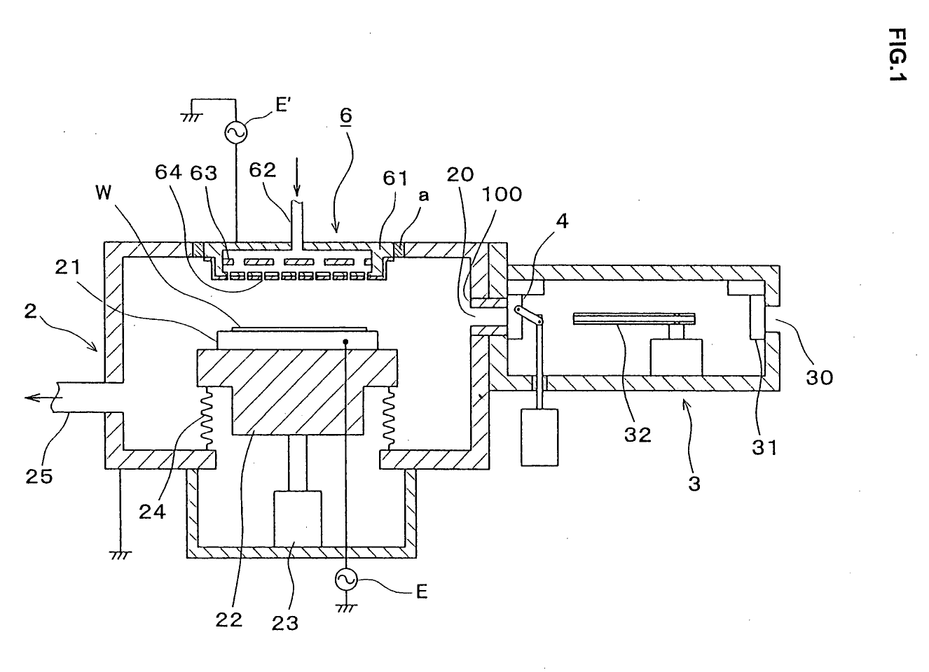

FIG. 1 shows the overall structure adopted in a plasma etching processing apparatus embodying the vacuum processing apparatus according to the present invention. A processing chamber 2, which is an airtight vacuum chamber, is grounded. An auxiliary vacuum chamber 3 is provided to ensure that the inner space of the processing chamber 2 is not directly exposed to the atmosphere and has a load lock function. The processing chamber 2 and the auxiliary vacuum chamber 3 are connected through a transfer port 20 formed through the wall surfaces, and a wafer W is transferred via the transfer port 20.

A susceptor 21 constituting a lower electrode, on which the wafer W is placed, is supported by a susceptor supporting member 22 having an insulating capability inside the processing chamber 2. The susceptor supporting member 22 can be moved up/down by an elevator unit 23. The space in which the elevator unit 23 is set is airtightly isolated from the atmosphere within the processing chamber 2 by a bellows member 24.

At the ceiling of the processing chamber 2, a gas injection unit 6, through which the processing gas is supplied, is provided facing opposite the susceptor 21. An evacuating pipe 25 linked to a vacuum pump (not shown) is connected at a side surface of the processing chamber 2. The gas injection unit 6, which is supported via an insulating member “a” at the top of the processing chamber 2 also functions as an upper electrode and includes a cylindrical gas diffusion chamber 61 and a gas supply pipe 62 connected at the upper surface of the gas diffusion chamber 61. At a middle stage and the bottom surface of the gas diffusion chamber 61, gas diffusion plates 63 and 64 having numerous holes punched therein are provided. The processing gas supplied through the gas supply pipe 62 is diffused and blended at these gas diffusion plates 63 and 64 and is then supplied into the processing chamber 2.

In addition, the susceptor 21, which also constitutes the lower electrode, is connected to a high-frequency source E. The upper electrode, which includes the gas injection unit 6, is connected to a high-frequency source E′. Thus, high-frequency power is applied between the upper and lower electrodes.

Gate valves 4 and 31, i.e., valve elements that can be opened/closed freely, are respectively provided at the transfer port 20 of the auxiliary vacuum chamber 3 toward the processing chamber 2 and at a transfer port 30 of the auxiliary vacuum chamber 3 on the atmosphere side, so as to seal the auxiliary vacuum chamber 3. Inside the auxiliary vacuum chamber 3, a transfer arm 32 used to transfer the wafer W, i.e., the workpiece, is mounted.

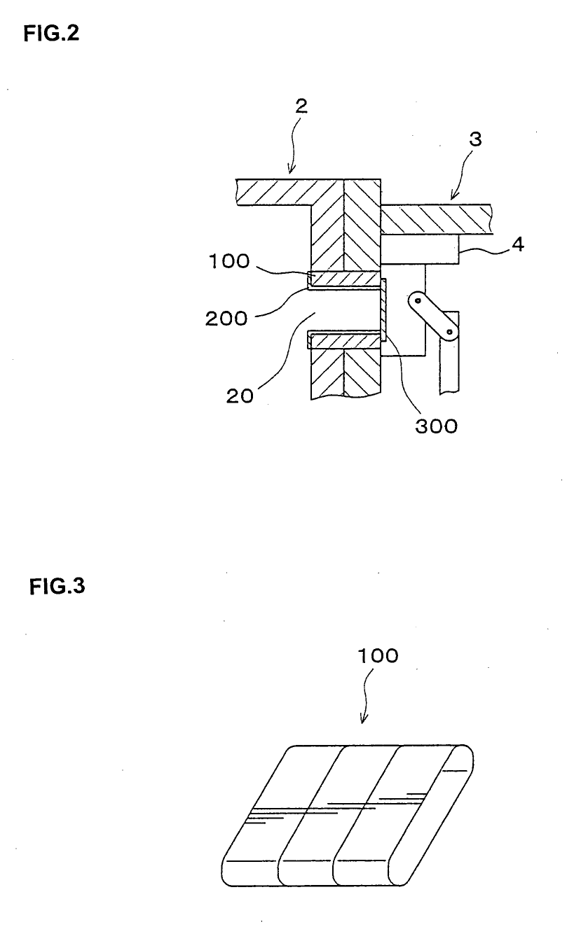

FIG. 2 is an enlarged sectional view of an area around the transfer port 20. As illustrated in the figure, a gate liner 100 is provided at the inner wall of the transfer port 20. The gate liner 100 is detachable and thus, it can be disengaged toward the processing chamber 2 and washed or the like for maintenance. In the embodiment, the gate liner 100 is constituted of aluminum with its surface coated with an insulating film 200. The insulating film 200 is constituted of a rare earth oxide spray-deposit film having a film thickness of 30 μm-200 μm and, more desirably, a film thickness of 50 μm-100 μm. In the embodiment, the insulating film 200 constituted of Y₂O₃ is formed over a thickness of 50 μm. The maximum thickness is 200 μm and, more desirably, 100 μm in the description given above, since an unnecessarily thick film is not economically desirable and does not improve performance.

FIG. 3 is a perspective of an example of the gate liner 100. In this example, the gate liner 100 is constituted by connecting three identical parts formed in a cylindrical shape with a substantially rectangular section. These parts can be connected and disengaged easily.

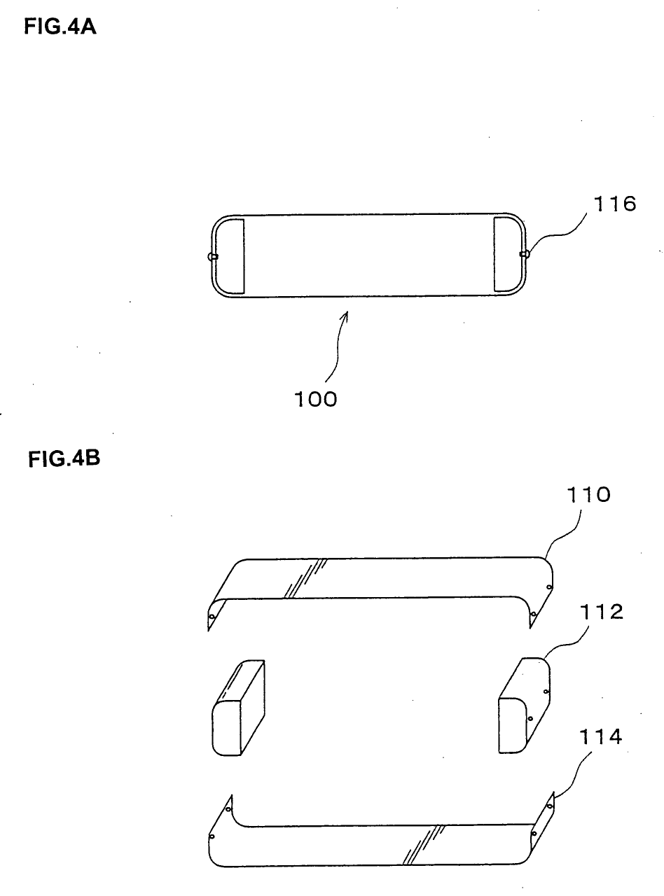

FIG. 4 presents another example of the gate liner 100. In FIG. 4A showing a sectional view of the assembled gate liner, the wafer is transferred along the direction perpendicular to the drawing sheet. FIG. 4B is an exploded view of the gate liner. In this example, the gate liner 100 is constituted of an upper part 110, side parts 112 and a lower part 114 which are connected and assembled by using screws 116, for instance.

Thus, even if damage occurs or the reaction product becomes deposited at the inner wall of the transfer port 20, the detachable gate liner 100 at the inner wall of the transfer port 20 alone must be disengaged to be washed or replaced. This greatly simplifies the maintenance work compared to the maintenance work executed to wash the transfer port 20 when no gate liner 100 is provided and also reduces the length of time required for the maintenance work.

In addition, even when damage requiring a replacement occurs at the gate liner 100, only the damaged part of the gate liner 100 constituted of a plurality of parts needs to be replaced. Thus, since the entire gate liner does not need to be replaced, a cost reduction is achieved.

Furthermore, the surface of the gate liner 100 is coated with the insulating film 200 constituted of a rare earth oxide spray-deposit film. Since a rare earth oxide has a high melting point and forms a strong chemical bond with oxygen, a stable condition can be maintained even when it is exposed to plasma. As a result, a high degree of plasma erosion resistance is achieved at the inner wall of the transfer port 20. Moreover, the large extent of protrusions and indentations at the film surface achieves a so-called deposit-trap effect whereby the deposited reaction product is not allowed to flake off easily, and thus, particles are not generated readily. Consequently, damage attributable to the plasma is prevented more effectively and the extents of metal contamination and dust generation are reduced over the related art. For this reason, the maintenance work does not need to be performed as frequently, thereby achieving an improvement in the throughput of the apparatus. The insulating film may be formed only at the inner surface which is exposed to the plasma, or it may be formed at all the surfaces.

As shown in FIG. 2, an insulating film 300 constituted of a rare earth oxide spray-deposit film is formed over the surface of the gate valve 4 covering the transfer port 20. The insulating film 300 constituted of a rare earth oxide spray-deposit film is formed to achieve a film thickness of 30 μm-200 μm and more desirably 50 μm-100 μm.

As described above, the insulating film 300 constituted of a rare earth oxide spray-deposit film is provided over the portion of the gate valve 4 covering the transfer port 20 exposed to the plasma. Since a rare earth oxide has a high fusion point and forms a strong chemical bond with oxygen, a stable condition can be maintained even when it is exposed to plasma. Thus, a structure with high plasma erosion resistance is achieved over this area, which effectively prevents damage attributable to plasma and reduces the extent of metal contamination and dust generation. As a result, the frequency with which the gate valve 4 must undergo maintenance work can be lowered to achieve an improvement in the throughput of the apparatus.

While the invention has been particularly shown and described with respect to preferred embodiments thereof by referring to the attached drawings, the present invention is not limited to these examples and it will be understood by those skilled in the art that various changes in form and detail may be made therein without departing from the spirit, scope and teaching of the invention.

While an explanation is given above in reference to the embodiments on an example in which the gate liner is constituted of aluminum and a rare earth oxide film is constituted of Y₂O₃, the present invention is not limited to this example. The gate liner may be constituted of an aluminum alloy, or an aluminum alloy with its surface covered with an anodic oxide oxidation coating film (alumite), instead of aluminum. In addition, a ceramic material or a sintered material constituted of, for instance, Al₂O₃ or a carbon material such as amorphous carbon is also ideal for the gate liner. Furthermore, the shape of the gate liner and the number of parts constituting the gate liner are not limited to those presented in the examples described above, and numerous conceivable variations are understood to be within the scope of the invention.

Moreover, while an explanation is given above in reference to the embodiments in which the present invention is adopted in an integrated chamber-type vacuum processing apparatus having an auxiliary vacuum chamber connected to the processing chamber, the present invention is not limited to this example. The present invention may be effectively adopted in a multi-chamber type vacuum processing apparatus having a transfer chamber connected to the processing chamber by providing a similar gate liner at the inner wall of a transfer port through which the processing chamber and the transfer chamber are connected with each other.

As explained above, the structure adopted in the present invention facilitates the maintenance work at the inner wall of the transfer port and the gate valve, allows the maintenance cycle to be extended and achieves an improvement in the throughput of the apparatus.

### Industrial Applicability

The present invention may be adopted in a vacuum processing apparatus that performs processing such as etching or chemical vapor deposition on a workpiece which may be a semiconductor wafer or a liquid crystal display substrate. More specifically, it can be effectively adopted to facilitate the maintenance work at the inner wall of a transfer port and at a gate valve, to extend the maintenance cycle and improve the throughput of the apparatus.

### Explanation of Reference Numerals

2 processing chamber

3 auxiliary vacuum chamber

4, 31 gate valve

6 gas injection unit

20, 30 transfer port

21 susceptor

22 susceptor supporting member

23 elevator unit

24 bellows member

25 evacuating pipe

32 transfer arm

61 gas diffusion chamber

62 gas supply pipe

63, 64 gas diffusion plate

100 gate liner

110 upper part

112 side part

114 lower part

116 screw

200, 300 insulating film

a insulating member

E,E′ high-frequency source

W wafer

What is claimed is:

1. A vacuum processing chamber comprising:
a detachable liner member provided at an inner wall of a transfer port formed at a wall surface of a vacuum processing chamber, through which a workpiece is transferred.

2. A vacuum processing chamber comprising:
a detachable liner member provided at an inner wall of a transfer port formed at a wall surface of a vacuum processing chamber, through which a workpiece is transferred, wherein:
said liner member is constituted of a plurality of members.

3. A vacuum processing chamber comprising:
a detachable liner member provided at an inner wall of a transfer port formed at a wall surface of a vacuum processing chamber, through which a workpiece is transferred, wherein:
said liner member is constituted of a plurality of members; and
an insulating film is coated onto a surface of said liner member.

4. A vacuum processing chamber comprising:
a detachable liner member provided at an inner wall of a transfer port formed out a wall surface of a vacuum processing chamber, through which a workpiece is transferred, wherein:
said liner member is constituted of a plurality of members;
an insulating film is coated onto a surface of said liner member; and
said insulating film is constituted of a rare earth oxide spray-deposit film.

5. A vacuum processing chamber comprising:
a detachable liner member provided at an inner wall of a transfer port formed at a wall surface of a vacuum processing chamber, through which a workpiece is transferred, wherein:
said liner member is constituted of a plurality of members;
an insulating film is coated onto a surface of said liner member; and
said insulating film is constituted of Y₂O₃.

6. A vacuum processing chamber comprising:
a detachable liner member provided at an inner wall of a transfer port formed at a wall surface of a vacuum processing chamber, through which a workpiece is transferred, wherein:
an insulating film is coated onto a surface of said liner member.

7. A vacuum processing chamber comprising:
a detachable liner member provided at an inner wall of a transfer port formed at a wall surface of a vacuum processing chamber, through which a workpiece is transferred, wherein:
an insulating film is coated onto a surface of said liner member; and
said insulating film is constituted of a rare earth oxide spray-deposit film.

8. A vacuum processing chamber comprising:
a detachable liner member provided at an inner wall of a transfer port formed at a wall surface of a vacuum processing chamber, through which a workpiece is transferred, wherein:
an insulating film is coated onto a surface of said liner member; and
said insulating film is constituted of Y₂O₃.

9. A vacuum processing apparatus according to any of claims 1 through 8, wherein:
the film thickness of said insulating film is equal to or greater than 50 μm and equal to or smaller than 100 μm.

10. A vacuum processing apparatus comprising a gate valve that opens/closes a transfer port formed at a wall surface of a vacuum processing chamber, through which a workpiece is transferred, wherein:
a rare earth oxide spray-deposit film is formed at a surface of said gate valve over, at least, an area thereof covering said transfer port.

11. A vacuum processing apparatus comprising a gate valve that opens/closes a transfer port formed at a wall surface of a vacuum processing chamber, through which a workpiece is transferred, wherein:
a rare earth oxide spray-deposit film is formed at a surface of said gate valve over, at least, an area thereof covering said transfer port; and
said rare earth oxide spray-deposit film is constituted of Y₂O₃.

12. A vacuum processing apparatus according to claim 10 or 11, wherein:
the film thickness of said rare earth oxide spray-deposit film is equal to or greater than 50 μm and equal to or smaller than 100 μm.
